(19) United States
(12) Patent Application Publication
(10) Pub. No.: US 2013/0084407 A1
(43) Pub. Date: Apr. 4, 2013

(54) PLASMA-ENHANCED DEPOSITION OF COPPER-CONTAINING FILMS FOR VARIOUS APPLICATIONS USING AMIDINATE COPPER PRECURSORS

(71) Applicants: Christian DUSSARRAT, Wilmington, DE (US); Clement LANSALOT-MATRAS, Tsukuba (JP); Vincent M. OMARJEE, Albany, NY (US)

(72) Inventors: Christian DUSSARRAT, Wilmington, DE (US); Clement LANSALOT-MATRAS, Tsukuba (JP); Vincent M. OMARJEE, Albany, NY (US)

(73) Assignee: American Air Liquide, Inc., Fremont, CA (US)

(21) Appl. No.: 13/248,092

(22) Filed: Sep. 29, 2011

(51) Int. Cl. C23C 16/18; C23C 16/50

(52) U.S. Cl. 427/569

(57) ABSTRACT

The disclosure relates to a process for depositing a Copper, Gold or Silver containing film using a Copper, Gold or Silver guanidinate and/or Copper, Gold or Silver amidinate precursor, suitable for plasma deposition at temperature equal or lower than 120 degrees C., to a plasma deposition process carried out at a temperature equal or lower than 120 degrees C.

### TECHNICAL FIELD

The present invention relates to a process for the use of metal amidinate metal precursors for the deposition of metal containing film via Plasma Enhanced Atomic Layer Deposition (PEALD) or Plasma Enhanced Chemical Vapor Deposition (PECVD).

### BACKGROUND ART

Copper has displaced aluminum to become the standard back-end-of-line (BEOL) metallization material for advanced logic devices. Copper's benefits over aluminum for logic are now well-documented. Its lower resistivity allows line thickness to be reduced by nearly one-third while achieving similar sheet resistance.

The formation of Copper containing films via Chemical Vapor and Atomic Layer Deposition (CVD and ALD) are promising. Desirable properties of the Copper precursor for these applications are i) High volatility ii) Sufficient stability to avoid decomposition during handling and delivery iii) Appropriate reactivity.

Amidinate metal precursors are know as efficient precursors for high temperature thermal ALD or CVD processes. The Gordon research group at Harvard has for example demonstrated thermal ALD at a temperature as low as 160° C. of Copper(I) amidinate with the formation of pure, highly conductive, conformal, and strongly adherent to substrates Copper films. PUBLISHED PCT

PATENT APPLICATION W004/046417; Li, Zhengwen; Barry, Sean T.; Gordon, Roy G., Synthesis and Characterization of Copper(I) Amidinates as Precursors for ALD of Copper Metal, Inorganic Chemistry (2005), 44(6): 1728-1735; U.S. PUBLISHED PATENT APPLICATION 2006/0141155.

However, the temperature of deposition in thermal ALD can not be lower than 160 degrees C. because of the lower reactivity of the precursor with the reductant at that low temperature.

Xu et al. (ATMI—U.S. Pat. No. 7,166,732 and U.S. Pat. No.7,371,880) described the use of amidinate type Copper precursors for Copper deposition using thermal CVD or thermal ALD in the 150-400 degree C. temperature range. In WO/2007/142700, Chen (ATMI) et al. also reported the use of guanidinate type Copper precursors for Copper deposition in thermal conditions.

For industrial process reasons, deposition of Copper should be realized at low temperature, below 120 degrees C., which makes deposition of Copper particularly challenging. Others working on this same technical issue have proposed use of certain Copper amidinate precursors at temperatures below 150 degrees C. in thermal CVD or ALD process. U.S. PUBLISHED PATENT APPLICATION 2007/0281476; U.S. Pat. No. 6,818,783. Use of plasma depositions has been dismissed as unworkable due to plasma damage to the substrate. See, e.g., US2006/0141155, paragraph [0021].

### BRIEF SUMMARY OF THE INVENTION

Contrary to the prevailing view in the art, the present invention generally employs plasma depositions to lower the deposition temperature for Copper containing films. The invention is described in part by the following numbered sentences:

A method for depositing a Copper, Gold or Silver containing film comprising the step of providing a Copper, Gold or Silver guanidinate and/or Copper, Gold or Silver amidinate precursor, suitable for plasma deposition at temperature equal or lower than 120 degrees C., to a plasma deposition process comprising a deposition temperature equal or lower than 120 degrees C.

The method of paragraph [0012], wherein the deposition temperature is at a temperature of 20-120 degrees C.

The method of paragraph [0012], wherein the deposition temperature is at a temperature of 25-120 degrees C.

The method of paragraph [0012], wherein the deposition temperature is at a temperature of 50-120 degrees C.

The method of paragraph [0012], wherein the deposition temperature is at a temperature of 20-50 degrees C.

The method of any one of paragraphs [0012]-[0016], wherein the Copper, Gold or Silver containing film is deposited on a substrate coated with one or more of Ru, Ta, TaN, SiO₂.

The method of any one of paragraphs [0012]-[0016] or any combination of one of paragraphs [0012]-[0016] with paragraph [0017], comprising at least one co-reactant amine or reducing agent.

The method of any one of paragraphs [0012]-[0016] or any combination of one of paragraphs [0012]-[0016] with one or both of paragraphs [0017] or [0018], comprising providing at least one co-reactant oxygen source selected from on or more of O₂, O₃, H₂O, H₂O₂, NO, NO₂, a carboxylic acid, or a diethylsilane.

The method of any one of paragraphs [0012]-[0016] or any combination of one of paragraphs [0012]-[0016] with one or more of paragraphs [0017]-[0019], wherein the plasma deposition process is a PECVD process.

The method of any one of paragraphs [0012]-[0016] or any combination of one of paragraphs [0012]-[0016] with one or more of paragraphs [0017]-[0020], wherein the plasma deposition process is a PEALD process comprising a plurality of cycle.

The process of any one of paragraphs [0012]-[0016] or any combination of one of paragraphs [0012]-[0016] with one or more of paragraphs [0017]-[0021], wherein the Copper, Gold or Silver film is substantially pure Copper, Gold or Silver.

The method of any one of paragraphs [0012]-[0016] or any combination of one of paragraphs [0012]-[0016] with one or more of paragraphs [0017]-[0022], wherein the suitable Copper, Gold or Silver precursor has the structure of compound (I):

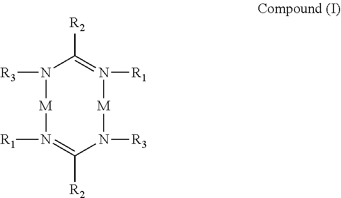

wherein:

M is Cu, Au or Ag: and

R₁ and R₃ are independently selected from H, a C1-C5 alkyl group, and Si(R′)₃, where R′ is independently selected from H, and a C1-C5 alkyl group. R₂ is independently selected from H, a C1-C5 alkyl group, and NR′R″, where R′ and R″ are independently selected from C1-C5 alkyl groups.

### DISCLOSURE OF INVENTION

The present invention relates to a process for the use of Copper amidinate metal precursors for the deposition of Copper containing films via Plasma Enhanced Atomic Layer Deposition (PEALD) or Plasma Enhanced Chemical Vapor Deposition (PECVD). Plasma improves deposition rates and/or film properties at deposition temperatures below 120 degrees C. The identification of plasma compatible Copper amidinate precursors permits the application of plasma to Copper depositions to derive the benefits of PECVD or PEALD and achieve acceptable deposition rates and film properties at the industrially required temperatures.

In some embodiments, the present invention provides methods of depositing pure Copper film by plasma enhanced atomic layer deposition (PEALD) and plasma enhanced chemical vapor deposition (PECVD). “Pure Copper” is defined as at least 90% copper such as 95% or more copper, 99% or more copper or 99.9% or more copper.

In some embodiments of the invention, Copper amidinate or Copper guanidinate is used at deposition temperatures lower than 120 degrees C. to form Copper films.

In some embodiments, the Copper deposition method includes the steps of providing a substrate; providing a vapor of a Copper guanidinate or a Copper amidinate precursor; and contacting the vapor including the at least one Copper precursor with the substrate (and typically directing the vapor to the substrate) to form a Copper containing layer on at least one surface of the substrate at temperature of 120 degrees C. or lower, preferably between 70 and 120 degrees C.

In some embodiments, the substrate is coated with a surface diffusion layer or a “glue layer”. Examples of diffusion layers or glue layers are without limitation Ru, TaN, Ta, SiO2, Si or any combination thereof.

In the foregoing embodiments, Copper may be replaced with Silver or Gold to achieve the same results and benefits.

One preferred metal precursor is represented by compound (I):

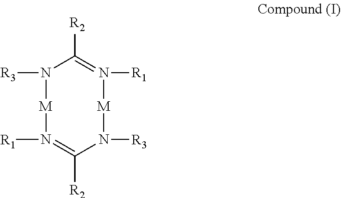

wherein M is a transition metal with +1 oxidation state selected from

Cu, Au, Ag, preferably M is Cu; and

R₁ and R₃ are independently selected from H, a C1-C5 alkyl group, and Si(R′)₃, where R′ is independently selected from H, and a C1-C5 alkyl group. R₂ is independently selected from H, a C1-C5 alkyl group, and NR′R″, where R′ and R″ are independently selected from C1-C5 alkyl groups.

Deposition conditions for the invention include temperatures in the range of 20-150 degrees C., preferably below 120 degrees C. such as 25-120 degrees C., 50-120 degrees C., or 20-50 degrees C.

Deposition conditions for the invention may also include pressures ranging from 0.5 mTorr to 20 Torr to deposit films having the general formula M, MₖSiₗ, MₙOₘ or MₓN_{y}O_{z}. Film composition will be dependent on the application. Where k, I, m, n, x, y range from 1 to 6, inclusive.

The deposition may include one or more co-reactants such as an amine containing reactant or a reducing agent. Exemplary co-reactants are H₂, NH₃, BuNH₂, B2H₆, GeH₄, SnH₄, AlH₃, or an alkyl silane containing a Si—H bond.

The deposition may include one or more co-reactant oxygen sources preferably O₂, O₃, H₂O, H₂O₂, NO, NO₂, a carboxylic acid, dimethylsilane.

The metal precursor may be delivered in neat form or in a blend with a suitable solvent, preferably Ethyl benzene, Xylenes, Mesitylene, Decane, Dodecane in different concentrations.

In some embodiments, preferred applications but not limited to could be Metal deposition on silicon to ultimately form metal silicide, metal deposition on Ta, TaN or WN to ultimately form metal layer, metal oxide deposition for ReRAM applications.

What is claimed is:

1. A process for depositing a Copper, Gold or Silver containing film comprising the step of providing a Copper, Gold or Silver guanidinate and/or Copper, Gold or Silver amidinate precursor, suitable for plasma deposition at temperature equal or lower than 120 degrees C., to a plasma deposition process comprising a deposition temperature equal or lower than 120 degrees C.

2. The method of claim 1, wherein the deposition temperature is at a temperature of 20-120 degrees C.

3. The method of claim 1, wherein the deposition temperature is at a temperature of 25-120 degrees C.

4. The method of claim 1, wherein the deposition temperature is at a temperature of 50-120 degrees C.

5. The method of claim 1, wherein the deposition temperature is at a temperature of 20-50 degrees C.

6. The method of claim 1, wherein the Copper, Gold or Silver containing film is deposited on a substrate coated with one or more of Ru, Ta, TaN, SiO₂.

7. The method of claim 1, comprising at least one co-reactant amine or reducing agent.

8. The method of claim 1, comprising providing at least one co-reactant oxygen source selected from on or more of O₂, O₃, H₂O, H₂O₂, NO, NO₂, a carboxylic acid, or a diethylsilane.

9. The method of claim 1, wherein the plasma deposition process is a PECVD process.

10. The method of claim 7, wherein the plasma deposition process is a PEALD process comprising a plurality of cycle.

11. The process of claim 1, wherein the Copper, Gold or Silver film is substantially pure Copper, Gold or Silver.

12. The method of claim 1, wherein the suitable Copper, Gold or Silver precursor has the structure of compound (I) 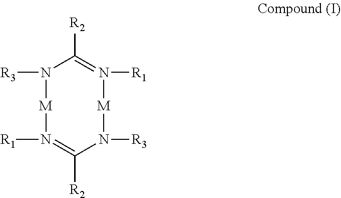
wherein:
M is Cu, Au or Ag; and
R₁ and R₃are independently selected from H, a C1-C5 alkyl group, and Si(R′)₃, where R′ is independently selected from H, and a C1-C5 alkyl group. R₂ is independently selected from H, a C1-C5 alkyl group, and NR′R″, where R′ and R″ are independently selected from C1-C5 alkyl groups.
